(19) United States
(12) Patent Application Publication
(10) Pub. No.: US 2004/0164315 A1
(43) Pub. Date: Aug. 26, 2004

(54) Structure and device including a tunneling piezoelectric switch and method of forming same

(75) Inventor: Alexander A. Demkov, Phoenix, AZ (US)

Correspondence Address: OBLON, SPIVAK, MCCLELLAND, MAIER & NEUSTADT, P.C., 1940 DUKE STREET, ALEXANDRIA, VA, 22314, US

(73) Assignee: MOTOROLA, INC., Schaumburg, IL (US)

(21) Appl. No.: 10/372,281

(22) Filed: Feb. 25, 2003

(51) Int. Cl. H01L 29/74

(52) U.S. Cl. 257/107

(57) ABSTRACT

Tunneling piezoelectric switch structures including high quality epitaxial layers of monocrystalline materials (26) grown overlying monocrystalline substrates (22) such as large silicon wafers are disclosed. The structures includes an accommodating buffer layer (24) spaced apart from a silicon wafer by an amorphous interface layer (28) of silicon oxide. The amorphous interface layer dissipates strain and permits the growth of a high quality monocrystalline oxide accommodating buffer layer.

### FIELD OF THE INVENTION

This invention relates generally to semiconductor structures and devices and to a method for their fabrication, and more specifically to semiconductor structures and devices and to the fabrication and use of semiconductor structures, devices, and integrated circuits that include a tunneling piezoelectric switch.

### BACKGROUND OF THE INVENTION

Semiconductor devices often include multiple layers of conductive, insulating, and semiconductive layers. Often, the desirable properties of such layers improve with the crystallinity of the layer. For example, the electron mobility and electron lifetime of semiconductive layers improve as the crystallinity of the layer increases; the free electron concentration of conductive layers and the electron charge displacement and electron energy recoverability of insulative or dielectric films improve as the crystallinity of these layers increases; and the desirable characteristic of the piezoelectric material—i.e., the piezoelectric effect—increases as the crystallinity of the material increases.

For many years, attempts have been made to grow various monolithic thin films on a foreign substrate such as silicon (Si). To achieve optimal characteristics of the various monolithic layers, however, a monocrystalline film of high crystalline quality and/or a polycrystalline film of a desired crystalline orientation is desired. Attempts have been made, for example, to grow various monocrystalline layers on a substrate such as germanium, silicon, and various insulators. These attempts have generally been unsuccessful because lattice mismatches between the host crystal and the grown crystal have caused the resulting layer of material to be of low crystalline quality.

If a large area thin film of high quality crystalline material were available at low cost, a variety of semiconductor devices could advantageously be fabricated in or using that film at a low cost compared to the cost of fabricating such devices beginning with a bulk wafer of the material. In addition, if a thin film of high quality crystalline material could be realized beginning with a bulk wafer such as a silicon wafer, an integrated device structure could be achieved that took advantage of the best properties of both the silicon and the high quality crystalline material.

Accordingly, a need exists for a semiconductor structure that provides a high quality crystalline film or layer over another monocrystalline material and for a process for making such a structure. Such films can be used to form, for example, piezoelectric switches suitable for use in memory and logic circuits.

### BRIEF DESCRIPTION OF THE DRAWINGS

The present invention is illustrated by way of example and not limitation in the accompanying figures, in which like references indicate similar elements, and in which:

FIGS. 1, 2, and 3 illustrate schematically, in cross section, device structures in accordance with various embodiments of the invention;

FIG. 4 illustrates graphically the relationship between maximum attainable film thickness and lattice mismatch between a host crystal and a grown crystalline overlayer;

FIG. 5 illustrates a process for forming a structure in accordance with the present invention; and

FIGS. 6 and 7 illustrate schematically, in cross section, device structures that can be used in accordance with various embodiments of the invention;

Skilled artisans will appreciate that elements in the figures are illustrated for simplicity and clarity and have not necessarily been drawn to scale. For example, the dimensions of some of the elements in the figures may be exaggerated relative to other elements to help to improve understanding of embodiments of the present invention.

### DETAILED DESCRIPTION OF THE DRAWINGS

FIG. 1 illustrates schematically, in cross section, a portion of a semiconductor structure 20 in accordance with an embodiment of the invention. Semiconductor structure 20 includes a monocrystalline substrate 22, accommodating buffer layer 24 comprising a monocrystalline material, and a crystalline material layer 26. In this context, the term “monocrystalline” shall have the meaning commonly used within the semiconductor industry. The term shall refer to materials that are a single crystal or that are substantially a single crystal and shall include those materials having a relatively small number of defects such as dislocations and the like as are commonly found in substrates of silicon or germanium or mixtures of silicon and germanium and epitaxial layers of such materials commonly found in the semiconductor industry. “Crystalline” shall mean materials having polycrystalline and/or monocrystalline structure. As explained in more detail below, structures in accordance with the present invention may be used to form tunneling switches suitable for use in logic and memory circuits.

In accordance with one embodiment of the invention, structure 20 also includes an amorphous intermediate layer 28 positioned between substrate 22 and accommodating buffer layer 24. Structure 20 may also include a template layer 30 between the accommodating buffer layer and crystalline material layer 26. As will be explained more fully below, the template layer helps to initiate the growth of the crystalline material layer on the accommodating buffer layer. The amorphous intermediate layer helps to relieve the strain in the accommodating buffer layer and by doing so, aids in the growth of a high crystalline quality accommodating buffer layer.

Substrate 22, in accordance with an embodiment of the invention, is a monocrystalline semiconductor or compound semiconductor wafer, preferably of large diameter. The wafer can be of, for example, a material from Group IV of the periodic table. Examples of Group IV semiconductor materials include silicon, germanium, mixed silicon and germanium, mixed silicon and carbon, mixed silicon, germanium and carbon, and the like. Preferably substrate 22 is a wafer containing silicon or germanium, and most preferably is a high quality monocrystalline silicon wafer as used in the semiconductor industry. Accommodating buffer layer 24 is preferably a monocrystalline oxide or nitride material epitaxially grown on the underlying substrate. In accordance with one embodiment of the invention, amorphous intermediate layer 28 is grown on substrate 22 at the interface between substrate 22 and the growing accommodating buffer layer by the oxidation of substrate 22 during the growth of layer 24. The amorphous intermediate layer serves to relieve strain that might otherwise occur in the monocrystalline accommodating buffer layer as a result of differences in the lattice constants of the substrate and the buffer layer. As used herein, lattice constant refers to the distance between atoms of a cell measured in the plane of the surface. If such strain is not relieved by the amorphous intermediate layer, the strain may cause defects in the crystalline structure of the accommodating buffer layer. Defects in the crystalline structure of the accommodating buffer layer, in turn, would make it difficult to achieve a high quality crystalline structure in crystalline material layer 26 which may comprise a piezoelectric material, a semiconductor material, a compound semiconductor material, or another type of material such as a metal or a non-metal, or a combination of these materials.

Accommodating buffer layer 24 is preferably a monocrystalline oxide or nitride material selected for its crystalline compatibility with the underlying substrate and with the overlying material layer. For example, the material could be an oxide or nitride having a lattice structure closely matched to the substrate and to the subsequently applied crystalline material layer. Materials that are suitable for the accommodating buffer layer include metal oxides such as the alkaline earth metal titanates, alkaline earth metal zirconates, alkaline earth metal hafnates, alkaline earth metal tantalates, alkaline earth metal ruthenates, alkaline earth metal niobates, alkaline earth metal vanadates, alkaline earth metal tin-based perovskites, lanthanum aluminate, lanthanum scandium oxide, and other perovskite oxide materials, and gadolinium oxide. Additionally, various nitrides such as gallium nitride, aluminum nitride, and boron nitride may also be used for the accommodating buffer layer. Most of these materials are insulators, although strontium ruthenate, for example, is a conductor. Generally, these materials are metal oxides or metal nitrides, and more particularly, these metal oxides or nitrides typically include at least two different metallic elements. In some specific applications, the metal oxides or nitrides may include three or more different metallic elements.

Amorphous interface layer 28 is preferably an oxide formed by the oxidation of the surface of substrate 22, and more preferably is composed of a silicon oxide. The thickness of layer 28 is sufficient to relieve strain attributed to mismatches between the lattice constants of substrate 22 and accommodating buffer layer 24. Typically, layer 28 has a thickness in the range of approximately 0.5-5 nm.

The material for crystalline material layer 26 can be selected, as desired, for a particular structure or application. For example, the crystalline material of layer 26 may comprise a monocrystalline compound semiconductor which can be selected, as needed for a particular semiconductor structure, from any of the Group IIIA and VA elements (III-V semiconductor compounds), mixed III-V compounds, Group II (A or B) and VIA elements (II-VI semiconductor compounds), mixed II-VI compounds, Group IV and VI elements (IV-VI semiconductor compounds), mixed IV-VI compounds, Group IV elements (Group IV semiconductors), and mixed Group IV compounds. Examples include gallium arsenide (GaAs), gallium indium arsenide (GaInAs), gallium aluminum arsenide (GaAlAs), indium phosphide (InP), cadmium sulfide (CdS), cadmium mercury telluride (CdHgTe), zinc selenide (ZnSe), zinc sulfur selenide (ZnSSe), lead selenide (PbSe), lead telluride (PbTe), lead sulfide selenide (PbSSe), silicon (Si), germanium (Ge), silicon germanium (SiGe), silicon germanium carbide (SiGeC), zinc oxide (ZnO), and the like. However, crystalline material layer 26 may also comprise other semiconductor materials, metals, or non-metal materials which are used in the formation of semiconductor structures, devices and/or integrated circuits.

In accordance with one exemplary embodiment of the invention, layer 26 includes a crystalline layer of Pb(Zr,Ti)O₃; e.g., Pb_{0.4}Zr_{0.6}TiO₃. In accordance with one aspect of this exemplary embodiment, piezoelectric PZT layer 26 is monocrystalline. In accordance with other aspects of this embodiment, layer 26 is a polycrystalline layer of PZT, in which the domains of the polycrystalline material are preferably aligned such that the dᵢⱼ axis of the crystals is perpendicular or parallel to the surface of substrate 22, depending on the orientation of the piezoelectric device, as described below. To provide the desired piezoelectric effect, layer 26 is preferably about 30-500 nm thick.

Appropriate materials for template 30 are discussed below. Suitable template materials chemically bond to the surface of the accommodating buffer layer 24 at selected sites and provide sites for the nucleation of the epitaxial growth of crystalline material layer 26. When used, template layer 30 has a thickness ranging from about 1 to about 10 monolayers.

FIG. 2 illustrates, in cross section, a portion of a semiconductor structure 40 in accordance with a further embodiment of the invention. Structure 40 is similar to the previously described semiconductor structure 20, except that an additional buffer layer 32 is positioned between accommodating buffer layer 24 and crystalline material layer 26. Specifically, the additional buffer layer 32 is positioned between template layer 30 and the overlying layer of crystalline material. The additional buffer layer serves to provide a lattice compensation when the lattice constant of the accommodating buffer layer cannot be adequately matched to the overlying crystalline material layer.

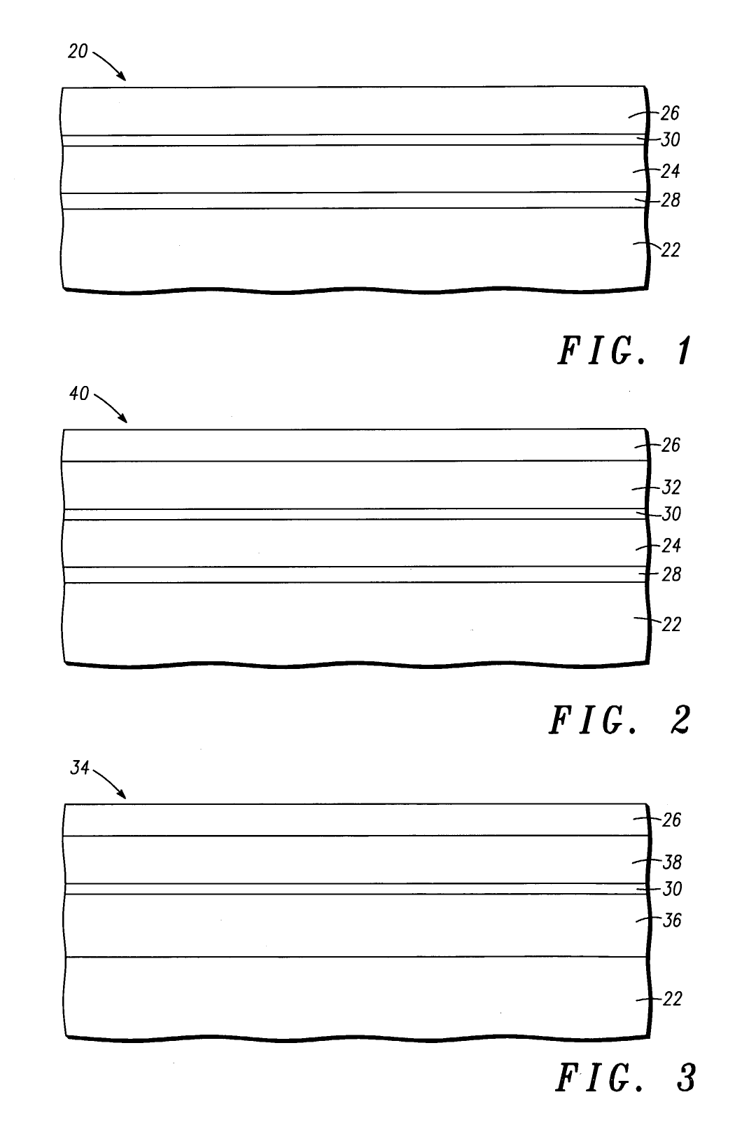

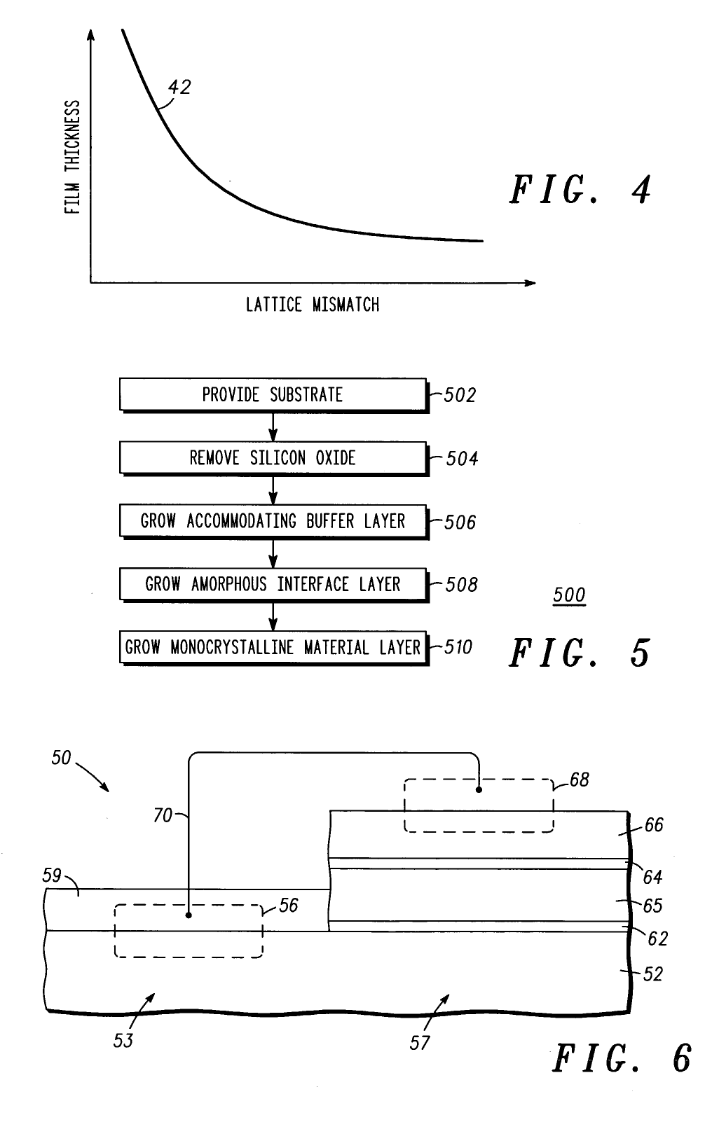

FIG. 3 schematically illustrates, in cross section, a portion of a semiconductor structure 34 in accordance with another exemplary embodiment of the invention. Structure 34 is similar to structure 20, except that structure 34 includes an amorphous layer 36, rather than accommodating buffer layer 24 and amorphous interface layer 28, and an additional crystalline layer 38.

As explained in greater detail below, amorphous layer 36 may be formed by first forming an accommodating buffer layer and an amorphous interface layer in a similar manner to that described above. Crystalline layer 38 is then formed (e.g., by epitaxial growth) overlying the monocrystalline accommodating buffer layer. The accommodating buffer layer may then be optionally exposed to an anneal process to convert at least a portion of the monocrystalline accommodating buffer layer to an amorphous layer. Amorphous layer 36 formed in this manner comprises materials from both the accommodating buffer and interface layers, which amorphous layers may or may not amalgamate. Thus, layer 36 may comprise one or two amorphous layers. Formation of amorphous layer 36 between substrate 22 and additional crystalline layer 26 (subsequent to layer 38 formation) relieves stresses between layers 22 and 38 and provides strain relief for subsequent processing—e.g., crystalline material layer 26 formation.

The processes previously described above in connection with FIGS. 1 and 2 are adequate for growing crystalline material layers over a monocrystalline substrate. However, the process described in connection with FIG. 3, which includes transforming at least a portion of a monocrystalline accommodating buffer layer to an amorphous oxide layer, may be better for growing crystalline material layers because it allows any strain in layer 26 to relax.

Additional monocrystalline layer 38 may include any of the materials described throughout this application in connection with either of crystalline material layer 26 or additional buffer layer 32. For example, when crystalline material layer 26 comprises a monocrystalline semiconductor or compound semiconductor material, layer 38 may include monocrystalline Group IV, monocrystalline compound semiconductor materials, or other monocrystalline materials including oxides and nitrides.

In accordance with one exemplary embodiment of the invention, layer 38 include a monocrystalline conductive material layer to facilitate electrical contract to layer 26, while allowing for monocrystalline growth of layer 26 overlying layer 38. Exemplary conductive monocrystalline materials suitable for use with the present invention include (La,Sr)CoO₃; e.g., La_{0.5}Sr_{0.5}CoO₃, having a thickness greater than 30 nm and more preferably having a thickness of about 30-100 nm.

In accordance with another embodiment of the present invention, additional crystalline layer 38 serves as an anneal cap during layer 36 formation and as a template for subsequent layer 26 formation. Accordingly, layer 38 is preferably thick enough to provide a suitable template for layer 26 growth (at least one monolayer) and thin enough to allow layer 38 to form with the desired crystalline structure.

In accordance with yet another embodiment of the invention, additional crystalline layer 38 comprises crystalline material (e.g., a material discussed above in connection with crystalline layer 26) that is thick enough to form devices within layer 38. In this case, a semiconductor structure in accordance with the present invention does not include crystalline material layer 26. In other words, the semiconductor structure in accordance with this embodiment only includes one crystalline layer disposed above amorphous oxide layer 36.

The following non-limiting, illustrative examples illustrate various combinations of materials useful in structures 20, 40, and 34 in accordance with various alternative embodiments of the invention. These examples are merely illustrative, and it is not intended that the invention be limited to these illustrative examples.

### EXAMPLE 1

In accordance with one embodiment of the invention, monocrystalline substrate 22 is a silicon substrate typically (001) oriented. The silicon substrate can be, for example, a silicon substrate as is commonly used in making complementary metal oxide semiconductor (CMOS) integrated circuits having a diameter of about 200-300 mm. In accordance with this embodiment of the invention, accommodating buffer layer 24 is a monocrystalline layer of Sr_{z}Ba_{1-z}TiO₃ where z ranges from 0 to 1 and the amorphous intermediate layer is a layer of silicon oxide (SiOₓ) formed at the interface between the silicon substrate and the accommodating buffer layer. The value of z is selected to obtain one or more lattice constants closely matched to corresponding lattice constants of the subsequently formed layer 26. The lattice structure of the resulting crystalline oxide exhibits a substantially 45 degree rotation with respect to the substrate silicon lattice structure. The accommodating buffer layer can have a thickness of about 2 to about 100 nanometers (nm) and preferably has a thickness of about 5 nm. In general, it is desired to have an accommodating buffer layer thick enough to isolate crystalline material layer 26 from the substrate to obtain the desired electrical and optical properties. Layers thicker than 100 nm usually provide little additional benefit while increasing cost unnecessarily; however, thicker layers may be fabricated if needed. The amorphous intermediate layer of silicon oxide can have a thickness of about 0.5-5 nm, and preferably a thickness of about 1 to 2 nm.

In accordance with this embodiment of the invention, crystalline material layer 26 is a monocrystalline layer of PZT material, having a thickness of about 1 nm to about 100 micrometers (μm) and preferably a thickness of about 0.5 μm to 10 μm. The thickness generally depends on the application for which the layer is being prepared.

### EXAMPLE 2

This example provides exemplary materials useful in structure 34, as illustrated in FIG. 3. Substrate material 22, template layer 30, and crystalline material layer 26 may be the same as those described above in connection with example 1 or example 2.

Amorphous layer 36 is an amorphous oxide layer which is suitably formed of a combination of amorphous intermediate layer materials (e.g., layer 28 materials as described above) and accommodating buffer layer materials (e.g., layer 24 materials as described above). For example, amorphous layer 36 may include a combination of SiOₓ and Sr_{z}Ba_{1-z}, TiO₃ (where z ranges from 0 to 1), which combine or mix, at least partially, during an anneal process to form amorphous oxide layer 36.

The thickness of amorphous layer 36 may vary from application to application and may depend on such factors as desired insulating properties of layer 36, type of crystalline material comprising layer 26, and the like. In accordance with one exemplary aspect of the present embodiment, layer 36 thickness is about 1 nm to about 100 nm, preferably about 1-10 nm, and more preferably about 3-5 nm.

In accordance with the illustrative embodiment, layer 38 comprises a monocrystalline material that can be grown epitaxially over a monocrystalline oxide material such as material used to form accommodating buffer layer 24. In accordance with one aspect of this embodiment, layer 38 includes the same materials as those comprising layer 26; however, layer 38 may include materials different from those used to form layer 26. In accordance with another aspect of this embodiment, layer 38 is about 1 nm to about 500 nm thick.

Referring again to FIGS. 1-3, substrate 22 is a monocrystalline substrate such as a monocrystalline silicon or gallium arsenide substrate. The crystalline structure of the monocrystalline substrate is characterized by a lattice constant and by a lattice orientation. In similar manner, accommodating buffer layer 24 is also a monocrystalline material and the lattice of that monocrystalline material is characterized by a lattice constant and a crystal orientation. The lattice constants of the accommodating buffer layer and the monocrystalline substrate must be closely matched or, alternatively, must be such that upon rotation of one crystal orientation with respect to the other crystal orientation, a substantial match in lattice constants is achieved. In this context the terms “substantially equal” and “substantially matched” mean that there is sufficient similarity between the lattice constants to permit the growth of a high quality crystalline layer on the underlying layer.

FIG. 4 illustrates graphically the relationship of the achievable thickness of a grown crystal layer of high crystalline quality as a function of the mismatch between the lattice constants of the host crystal and the grown crystal. Curve 42 illustrates the boundary of high crystalline quality material. The area to the right of curve 42 represents layers that have a large number of defects. With no lattice mismatch, it is theoretically possible to grow an infinitely thick, high quality epitaxial layer on the host crystal. As the mismatch in lattice constants increases, the thickness of achievable, high quality crystalline layer decreases rapidly. As a reference point, for example, if the lattice constants between the host crystal and the grown layer are mismatched by more than about 2%, monocrystalline epitaxial layers in excess of about 20 nm cannot be achieved.

In accordance with one embodiment of the invention, substrate 22 is typically a (001) oriented monocrystalline silicon wafer and accommodating buffer layer 24 is a layer of strontium barium titanate. Substantial (i.e., effective) matching of lattice constants between these two materials is achieved by rotating the crystal orientation of the titanate material by approximately 45° with respect to the crystal orientation of the silicon substrate wafer. The inclusion in the structure of amorphous interface layer 28, a silicon oxide layer in this example, if it is of sufficient thickness, serves to reduce strain in the titanate monocrystalline layer that might result from any mismatch in the lattice constants of the host silicon wafer and the grown titanate layer. As a result, in accordance with an embodiment of the invention, a high quality, thick, monocrystalline titanate layer is achievable.

Still referring to FIGS. 1-3, in accordance with exemplary embodiments of the invention, layer 26 is a layer of epitaxially grown monocrystalline material and that crystalline material is also characterized by a crystal lattice constant and a crystal orientation. The lattice constant of layer 26 may differ from the lattice constant of substrate 22. In this case, to achieve high crystalline quality in epitaxially grown monocrystalline layer 26, the accommodating buffer layer must be of high crystalline quality. In addition, in order to achieve high crystalline quality in layer 26, substantial matching between the crystal lattice constant of the host crystal, in this case, the monocrystalline accommodating buffer layer, and the grown crystal is desired. With properly selected materials this substantial matching of lattice constants is achieved as a result of rotation of the crystal orientation of the grown crystal with respect to the orientation of the host crystal.

FIG. 5 illustrates a process 500, in accordance with one embodiment of the invention, for fabricating a semiconductor structure such as the structures depicted in FIGS. 1-3. Process 500 starts by providing a monocrystalline semiconductor substrate comprising silicon or germanium (step 502). In accordance with a preferred embodiment of the invention, the semiconductor substrate is a silicon wafer having a (100) orientation. The substrate is oriented on axis or, at most, about 6° off axis, and preferably misoriented 1-3° off axis toward the [110] direction. At least a portion of the semiconductor substrate has a bare surface, although other portions of the substrate, as described below, may encompass other structures. The term “bare” in this context means that the surface in the portion of the substrate has been cleaned to remove any oxides, contaminants, or other foreign material. As is well known, bare silicon is highly reactive and readily forms a native oxide. The term “bare” is intended to encompass such a native oxide. A thin silicon oxide may also be intentionally grown on the semiconductor substrate, although such a grown oxide is not essential to the process in accordance with the invention. In order to epitaxially grow a monocrystalline oxide layer overlying the monocrystalline substrate, the native oxide layer must first be removed to expose the crystalline structure of the underlying substrate (step 504). The following process is preferably carried out by molecular beam epitaxy (MBE), although other epitaxial processes may also be used in accordance with the present invention. The native oxide can be removed by first thermally depositing a thin layer (preferably 1-3 monolayers) of strontium, barium, a combination of strontium and barium, or other alkaline earth metals or combinations of alkaline earth metals in an MBE apparatus. In the case where strontium is used, the substrate is then heated to a temperature above 720° C. as measured by an optical pyrometer to cause the strontium to react with the native silicon oxide layer. The strontium serves to reduce the silicon oxide to leave a silicon oxide-free surface. The resultant surface may exhibit an ordered (2×1) structure. If an ordered (2×1) structure has not been achieved at this stage of the process, the structure may be exposed to additional strontium until an ordered (2×1) structure is obtained. The ordered (2×1) structure forms a template for the ordered growth of an overlying layer of a monocrystalline oxide. The template provides the necessary chemical and physical properties to nucleate the crystalline growth of an overlying layer.

It is understood that precise measurement of actual temperatures in MBE equipment, as well as other processing equipment, is difficult, and is commonly accomplished by the use of a pyrometer or by means of a thermocouple placed in close proximity to the substrate. Calibrations can be performed to correlate the pyrometer temperature reading to that of the thermocouple. However, neither temperature reading is necessarily a precise indication of actual substrate temperature. Furthermore, variations may exist when measuring temperatures from one MBE system to another MBE system. For the purpose of this description, typical pyrometer temperatures will be used, and it should be understood that variations may exist in practice due to these measurement difficulties.

In accordance with an alternate embodiment of the invention, the native silicon oxide can be converted and the substrate surface can be prepared for the growth of a monocrystalline oxide layer by depositing an alkaline earth metal oxide, such as strontium oxide, strontium barium oxide, or barium oxide, onto the substrate surface by MBE at a low temperature and by subsequently heating the structure to a temperature of above 720° C. At this temperature a solid state reaction takes place between the strontium oxide and the native silicon oxide causing the reduction of the native silicon oxide and leaving an ordered (2×1) structure on the substrate surface. If an ordered (2×1) structure has not been achieved at this stage of the process, the structure may be exposed to additional strontium until an ordered (2×1) structure is obtained. Again, this forms a template for the subsequent growth of an ordered monocrystalline oxide layer.

Following the removal of the silicon oxide from the surface of the substrate, in accordance with one embodiment of the invention, the substrate is cooled to a temperature in the range of about 200-600° C., preferably 350°-550° C., and a layer of strontium titanate is grown on the template layer by molecular beam epitaxy (step 506). The MBE process is initiated by opening shutters in the MBE apparatus to expose strontium, titanium and oxygen sources. The ratio of strontium and titanium is approximately 1:1. The partial pressure of oxygen is initially set at a minimum value to grow stoichiometric strontium titanate at a growth rate of about 0.1-0.8 nm per minute, preferably 0.3-0.5 nm per minute. After initiating growth of the strontium titanate, the partial pressure of oxygen is increased above the initial minimum value (step 508). The stoichiometry of the titanium can be controlled during growth by monitoring RHEED patterns and adjusting the titanium flux. The overpressure of oxygen causes the growth of an amorphous silicon oxide layer at the interface between the underlying substrate and the strontium titanate layer. This step may be applied either during or after the growth of the strontium titanate layer. The growth of the amorphous silicon oxide layer results from the diffusion of oxygen through the strontium titanate layer to the interface where the oxygen reacts with silicon at the surface of the underlying substrate. The strontium titanate grows as an ordered (100) monocrystal with the (100) crystalline orientation rotated by 45° with respect to the underlying substrate. Strain that otherwise might exist in the strontium titanate layer because of the small mismatch in lattice constant between the silicon substrate and the growing crystal is relieved in the amorphous silicon oxide intermediate layer.

After the strontium titanate layer has been grown to the desired thickness, the monocrystalline strontium titanate is capped by a template layer that is conducive to the subsequent growth of an epitaxial layer of a desired crystalline material.

Following the formation of the template, material layer 26 is formed overlying the accommodating buffer layer. In accordance with one exemplary embodiment of the invention, layer 26 includes PZT material and is formed using a spin-on, sol-gel coating technique. After the material is spun onto layer 24, the PZT material is calcined and crystallized at a temperature of about 450° C. to about 800° C. to form a monocrystalline layer. PZT layer 26 may also be formed using PVD or CVD techniques.

In accordance with another embodiment of the invention, layer 26 is a monocrystalline compound semiconductor material layer of gallium arsenide. In this case, the MBE growth of the strontium titanate monocrystalline layer is capped by terminating the growth with up to 2 monolayers of titanium, up to 2 monolayers of strontium, up to 2 monolayers of titanium-oxygen or with up to 2 monolayers of strontium-oxygen. Following the formation of this capping layer, arsenic is deposited to form a Ti—As bond, a Ti—O—As bond or a Sr—O—As bond. Any of these form an appropriate template for deposition and formation of a gallium arsenide monocrystalline layer. Following the formation of the template, gallium is subsequently introduced to the reaction with the arsenic and gallium arsenide forms. Alternatively, 0.5-3 monolayers of gallium can be deposited on the capping layer to form a Sr—O—Ga bond, or a Ti—O—Ga bond, and arsenic is subsequently introduced with the gallium to form the GaAs.

The structure illustrated in FIG. 2 can be formed by the process discussed above with the addition of an additional buffer layer deposition step. The additional buffer layer 32 is formed overlying the template layer 30 before the deposition of the crystalline material layer 26. If the additional buffer layer 32 is a monocrystalline material comprising a compound semiconductor superlattice, such a superlattice can be deposited, by MBE for example, on the template 30 described above. If instead, the additional buffer layer is a monocrystalline material layer comprising a layer of germanium, the process above is modified to cap the first buffer layer of strontium titanate with a final template layer of either strontium or titanium and then by depositing germanium to react with the strontium or titanium. The germanium buffer layer can then be deposited directly on this template.

Structure 34, illustrated in FIG. 3, may be formed by growing an accommodating buffer layer 24, forming an amorphous oxide layer 28 over substrate 22, and growing layer 38 over the accommodating buffer layer, as described above. The accommodating buffer layer 24 and the amorphous oxide layer 28 are then exposed to a higher temperature anneal process sufficient to change the crystalline structure of the accommodating buffer layer from monocrystalline to amorphous, thereby forming an amorphous layer such that the combination of the amorphous oxide layer and the now amorphous accommodating buffer layer form a single amorphous oxide layer 36. Layer 26 is then subsequently grown over layer 38. Alternatively, the anneal process may be carried out subsequent to growth of layer 26.

In accordance with one aspect of this embodiment, layer 36 is formed by exposing substrate 22, the accommodating buffer layer 24, the amorphous oxide layer 28, and layer 38 to a rapid thermal anneal process with a peak temperature of about 700° C. to about 1000° C. (actual temperature) and a process time of about 5 seconds to about 20 minutes. However, other suitable anneal processes may be employed to convert the accommodating buffer layer to an amorphous layer in accordance with the present invention. For example, laser annealing, electron beam annealing, or “conventional” thermal annealing processes (in the proper environment) may be used to form layer 36. When conventional thermal annealing is employed to form layer 36, an overpressure of one or more constituents of layer 38 may be required to prevent degradation of layer 38 during the anneal process. Alternately, an appropriate anneal cap, such as silicon nitride, may be utilized to prevent the degradation of layer 38 during the anneal process with the anneal cap being removed after the annealing process.

As noted above, layer 38 of structure 34 may include any materials suitable for either of layers 32 or 26. Accordingly, any deposition or growth methods described in connection with either layer 32 or 26 may be employed to deposit layer 38.

The process described above illustrates a process for forming a semiconductor structure including a silicon substrate, an overlying oxide layer, and a crystalline material layer by the process of molecular beam epitaxy and spin-on sol-gel. The process can also be carried out by the process of chemical vapor deposition (CVD), metal organic chemical vapor deposition (MOCVD), migration enhanced epitaxy (MEE), atomic layer epitaxy (ALE), physical vapor deposition (PVD), chemical solution deposition (CSD), pulsed laser deposition (PLD), or the like. Further, by a similar process, other monocrystalline accommodating buffer layers such as alkaline earth metal titanates, zirconates, hafnates, tantalates, vanadates, ruthenates, niobates, alkaline earth metal tin-based perovskites, lanthanum aluminate, lanthanum scandium oxide, and gadolinium oxide can also be grown. Further, by a similar process such as MBE, other crystalline material layers comprising other III-V, II-VI, and IV-VI monocrystalline compound semiconductors, semiconductors, metals and non-metals can be deposited overlying the monocrystalline oxide accommodating buffer layer.

In accordance with one embodiment of the present invention, in order to provide for the formation of high quality crystalline material for layer 26, the starting substrate is off-cut or misoriented from the ideal (100) orientation by 0.5 to 6 degrees in any direction, and preferably 1 to 2 degrees toward the [110] direction. This offcut provides for steps or terraces on the silicon surface and it is believed that these substantially reduce the number of anti-phase domains in the overlying material, in comparison to a substrate having an offcut near 0 degrees or off cuts larger than 6 degrees. The greater the amount of off-cut, the closer the steps and the smaller the terrace widths become.

At very small angles, nucleation occurs at other than the step edges, decreasing the size of single phase domains. At high angles, smaller terraces decrease the size of single phase domains. Growing a high quality oxide, such as strontium titanate, upon a silicon surface causes surface features to be replicated on the surface of the oxide. The step and terrace surface features are replicated on the surface of the oxide, thus preserving directional cues for subsequent growth of material. Because the formation of the amorphous interface layer occurs after the nucleation of the oxide has begun, the formation of the amorphous interface layer does not disturb the step structure of the oxide.

Clearly, those embodiments specifically describing structures having PZT portions and semiconductor portions are meant to illustrate embodiments of the present invention and not limit the present invention. There are a multiplicity of other combinations and other embodiments of the present invention. For example, the present invention includes structures and methods for fabricating material layers which form semiconductor structures, devices and integrated circuits including other layers such as metal and non-metal layers. More specifically, the invention includes structures and methods for forming a compliant substrate which is used in the fabrication of semiconductor structures, devices and integrated circuits and the material layers suitable for fabricating those structures, devices, and integrated circuits. By using embodiments of the present invention, it is now simpler to integrate devices that include monocrystalline piezoelectric layers and compound semiconductor materials, as well as other material layers that are used to form those devices, with other components that work better or are easily and/or inexpensively formed within semiconductor or compound semiconductor materials. This allows a device to be shrunk, the manufacturing costs to decrease, and yield and reliability to increase.

In accordance with one embodiment of this invention, a monocrystalline semiconductor or compound semiconductor wafer can be used in forming crystalline material layers over the wafer. In this manner, the wafer is essentially a “handle” wafer used during the fabrication of electrical components within a crystalline layer overlying the wafer. Therefore, electrical components can be formed within material layers over a wafer of at least approximately 200 millimeters in diameter and possibly at least approximately 300 millimeters.

By the use of this type of substrate, the relatively inexpensive “handle” wafer overcomes the fragile nature of wafers fabricated of crystalline or monocrystalline material by placing the material over a relatively more durable and easy to fabricate base substrate. Fabrication costs for devices employing non-silicon crystalline materials should decrease because larger substrates can be processed more economically and more readily compared to the relatively smaller and more fragile substrates.

FIG. 6 illustrates schematically, in cross section, a device structure 50 in accordance with a further embodiment. Device structure 50 includes a monocrystalline semiconductor substrate 52, preferably a monocrystalline silicon wafer. Monocrystalline semiconductor substrate 52 includes two regions, 53 and 57. A semiconductor component generally indicated by the dashed line 56 is formed, at least partially, in region 53. Semiconductor component 56 can be a resistor, a capacitor, an active electrical component such as a diode or a transistor, an optoelectric component such as a photo detector, or an integrated circuit such as a CMOS integrated circuit. For example, semiconductor component 56 can be a CMOS integrated circuit configured to perform digital signal processing or another function for which silicon integrated circuits are well suited. The electrical semiconductor component in region 53 can be formed by conventional semiconductor processing as well known and widely practiced in the semiconductor industry. A layer of insulating material 59 such as a layer of silicon dioxide or the like may overlie semiconductor component 56.

Insulating material 59 and any other layers that may have been formed or deposited during the processing of semiconductor component 56 in region 53 are removed from the surface of region 57 to provide a bare silicon surface in that region. As is well known, bare silicon surfaces are highly reactive and a native silicon oxide layer can quickly form on the bare surface. A layer (preferably 1-3 monolayers) of strontium or strontium and oxygen is deposited onto the native oxide layer on the surface of region 57 and is reacted with the oxidized surface to form a first template layer (not shown). In accordance with one embodiment, a monocrystalline oxide layer is formed overlying the template layer by a process of molecular beam epitaxy. Reactants including strontium, titanium and oxygen are deposited onto the template layer to form the monocrystalline oxide layer. Initially during the deposition the partial pressure of oxygen is kept near the minimum necessary to fully react with the strontium and titanium to form a monocrystalline strontium titanate layer. The partial pressure of oxygen is then increased to provide an overpressure of oxygen and to allow oxygen to diffuse through the growing monocrystalline oxide layer. The oxygen diffusing through the strontium titanate reacts with silicon at the surface of region 57 to form an amorphous layer of silicon oxide 62 on second region 57 and at the interface between silicon substrate 52 and the monocrystalline oxide layer 65. Layers 65 and 62 may be subject to an annealing process as described above in connection with FIG. 3 to form a single amorphous accommodating layer.

In accordance with an embodiment, the step of depositing the monocrystalline oxide layer 65 is terminated by depositing a capping layer 64, which can be up to 3 monolayers of titanium, strontium, strontium and oxygen, or titanium and oxygen. A layer 66 of a monocrystalline compound semiconductor material is then deposited overlying capping layer 64 by a process of molecular beam epitaxy. The deposition of layer 66 is initiated by depositing a layer of gallium onto capping layer 64. This initial step is followed by depositing arsenic and gallium to form monocrystalline gallium arsenide 66. Alternatively, barium or a mix of barium and strontium can be substituted for strontium in the above example.

In accordance with a further embodiment, a semiconductor component, generally indicated by a dashed line 68 is formed in compound semiconductor layer 66. Semiconductor component 68 can be formed by processing steps conventionally used in the fabrication of gallium arsenide or other III-V compound semiconductor material devices. Semiconductor component 68 can be any active or passive component, and preferably is a semiconductor laser, light emitting diode, photodetector, heterojunction bipolar transistor (HBT), high frequency MESFET, pseudomorphic high electron mobility transistor (PHEMT), or other component that utilizes and takes advantage of the physical properties of compound semiconductor materials. A metallic conductor schematically indicated by the line 70 can be formed to electrically couple device 68 and device 56, thus implementing an integrated device that includes at least one component formed in silicon substrate 52 and one device formed in monocrystalline compound semiconductor material layer 66. Although illustrative structure 50 has been described as a structure formed on a silicon substrate 52 and having a strontium (or barium) titanate layer 65 and a gallium arsenide layer 66, similar devices can be fabricated using other substrates, monocrystalline oxide layers and other crystalline layers as described elsewhere in this disclosure.

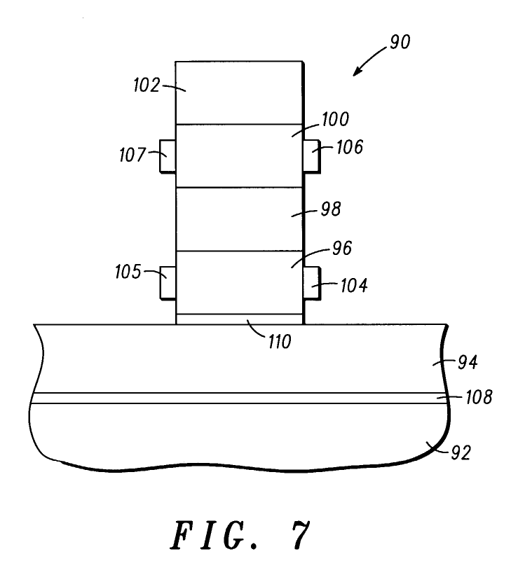

FIG. 7 illustrates a vertical configuration of a multiple-gate switch structure 90 in accordance with another embodiment of the invention. Structure 90 includes a monocrystalline substrate 92, an accommodating buffer layer 94, a first piezoelectric material portion 96, a first semiconductor portion 98, a second piezoelectric portion 100, a second semiconductor portion 102, a first gate including conductive portions 104, 105 and a second gate including conductive portions 106, 107. Structure 90 may also include an amorphous interface layer 108 and/or a template layer 110.

Substrate 92 and layers and portions 94-110 may include any of the corresponding materials described above in connection with FIGS. 1-3, and 6 and may be formed according to the method described above in connection with FIG. 5. By way of particular example, piezoelectric portions 96 and 100 may comprise PZT, semiconductor portions 98 and 102 may comprise silicon or gallium arsenide, and gate portions 104-107 may comprise metal or doped polysilicon material. In this case, piezoelectric layers 96 and 100 are preferably monocrystalline, such that monocrystalline layers of semiconductor material for portions 98 ad 102 may be grown overlying piezoelectric portions 96 and 100.

Structure 90 may be used to form a memory device or a double gate logic device. When structure 90 is used to form a memory device, writing and reading threshold voltages are controlled by applying a suitable voltage across the gate portions 104, 105 and 106, 107, with template layer 110 acting as a source and second semiconductor portion 102 as a drain. For example, a bias cam be applied across gate portions 104, 105 and/or 106,107 to maintain the state of the memory device during a read operation. This allows a reduction in a requisite write voltage and consequently allows for a faster write operation of the memory device.

Although illustrated with semiconductor material directly overlying piezoelectric portions 96 and 100, it is understood that suitable accommodating and amorphous layers as described herein may be interposed between the piezoelectric material and the semiconductor material. For example, an accommodating buffer layer of strontium barium titanate may be interposed between the piezoelectric portions and the semiconductor portions.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative rather than a restrictive sense, and all such modifications are intended to be included within the scope of present invention.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential features or elements of any or all the claims. As used herein, the terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus.

We claim:

1. A piezoelectric switch structure comprising:
a monocrystalline substrate;
an accommodating buffer layer overlying the monocrystalline substrate;
a first piezoelectric portion formed overlying the accommodating buffer layer; and.
a first semiconductor portion formed proximate the first piezoelectric portion, wherein the first piezoelectric portion and the first semiconductor portion are configured such that when a bias is applied across the first piezoelectric portion, the first piezoelectric portioned deforms and alters a tunneling rate between the first piezoelectric portion and the first semiconductor portion.

2. The piezoelectric switch structure of claim 1, further comprising an amorphous layer interposed between the monocrystalline substrate and the accommodating buffer layer.

3. The piezoelectric switch structure of claim 2, wherein the amorphous layer comprises silicon oxide.

4. The piezoelectric switch structure of claim 1, wherein the first piezoelectric portion comprises a material selected from ZnO and Pb(Zr,Ti)O₃.

5. The piezoelectric switch structure of claim 4, wherein the first piezoelectric portion comprises Pb_{0.4}Zr_{0.6}TiO₃.

6. The piezoelectric switch structure of claim 1, wherein first semiconductor portion is formed adjacent the first piezoelectric portion and formed overlying the accommodating buffer layer.

7. The piezoelectric switch structure of claim 1, wherein the first semiconductor portion comprises a material selected from the group consisting of silicon and gallium arsenide.

8. The piezoelectric switch structure of claim 1, wherein first semiconductor portion is formed overlying the first piezoelectric portion.

9. The piezoelectric switch structure of claim 8, further comprising a second piezoelectric portion formed overlying the first semiconductor portion and a second semiconductor portion overlying the second piezoelectric portion.

10. The piezoelectric switch structure of claim 9, wherein the second piezoelectric portion comprises a material selected from the group consisting of ZnO and Pb(Zr,Ti)O₃ and the second semiconductor portion comprises a material selected from the group consisting of silicon and gallium arsenide.

11. The piezoelectric switch structure of claim 1, further comprising an electronic device formed using the monocrystalline substrate.

12. A process for fabricating a piezoelectric switch structure comprising the steps of:
providing a monocrystalline substrate;
depositing a monocrystalline accommodating buffer film overlying the monocrystalline substrate;
epitaxially forming a first piezoelectric portion overlying the accommodating buffer film; and
forming a first monocrystalline semiconductor portion proximate the piezoelectric portion.

13. The process of claim 12, further comprising the step of forming an amorphous oxide interface layer containing at least silicon and oxygen at an interface between the accommodating buffer film and the monocrystalline silicon substrate.

14. The process of claim 12, further comprising the step of exposing the monocrystalline accommodating buffer film to a temperature to convert at least a portion of the monocrystalline accommodating buffer film to an amorphous structure.

15. The process of claim 12, further comprising the steps of:
forming a second piezoelectric portion overlying the first semiconductor portion; and
forming a second semiconductor portion overlying the second piezoelectric portion.

16. The process of claim 12, wherein the step of epitaxially forming a first piezoelectric portion comprises applying Pb(Zr,Ti)O₃ using a spin-on, sol-gel technique.

17. The process of claim 16, further comprising the step of exposing the PB(Zr,Ti)O₃ material to calcine process.

18. A vertical piezoelectric switch structure comprising:
a monocrystalline silicon substrate;
an accommodating buffer layer comprising strontium titanate;
a first piezoelectric material portion formed overlying and in contact with the accommodating buffer layer; and
a first semiconductor material portion formed overlying the first piezoelectric material portion.

19. The vertical piezoelectric switch structure of claim 18, further comprising a first gate formed about a portion of the first piezoelectric material portion.

20. The vertical piezoelectric switch structure of claim 18, wherein the first piezoelectric material portion comprises Pb(Zr,Ti)O₃.

21. The vertical piezoelectric switch structure of claim 18, wherein the first semiconductor material portion comprises a material selected from the group consisting of silicon and gallium arsenide.

22. The vertical piezoelectric switch structure of claim 18, further comprising:
a second piezoelectric material portion formed overlying the first semiconductor material portion;
a second semiconductor material portion overlying the second piezoelectric material portion;
and a second gate formed about a portion of the second piezoelectric material portion.
